(19) United States
(12) Patent Application Publication
(10) Pub. No.: US 2018/0162732 A1
(43) Pub. Date: Jun. 14, 2018

(54) METHOD OF PREPARING METAL CHALCOGENIDE NANOMATERIALS

(71) Applicant: Baoshan Iron & Steel Co., Ltd., Shanghai (CN)

(72) Inventors: Zhen Li, Wollongong (AU); Xinqi Chen, Wollongong (AU); Shixue Dou, Wollongong (AU)

(21) Appl. No.: 15/579,138

(22) PCT Filed: Jun. 1, 2015
(86) PCT No.: PCT/CN2015/080452

§ 371 Date: Dec. 1, 2017

(51) Int. Cl. C01B 19/00; H01L 35/34; H01L 35/26

(52) U.S. Cl. CPC C01B 19/007; H01L 35/34; H01L 35/26; H01G 9/2022; C01P 2004/16; C01P 2004/13; C01P 2004/34; C01P 2006/40

(57) ABSTRACT

Disclosed are chalcogenide nanomaterials, preferably metal chalcogenide nanomaterials, for example, copper, lead and/or silver chalcogenide nanomaterials. Also provided is a method or process of synthesizing or preparing a chalcogenide nanomaterial, preferably a metal chalcogenide nanomaterial. In an example, a wet-chemical method is used to prepare metal chalcogenide nanomaterials, preferably in a solvent and in the presence of one or more organic ligands. Another example method involves producing metal chalcogenide nanomaterial and includes the steps of forming a mixture of a metal precursor, a chalcogen-based ligand, a solvent and a chalcogen precursor, heating the mixture at a reaction temperature for a duration of reaction time, and separating a produced metal chalcogenide nanomaterial.

### TECHNICAL FIELD

The present invention generally relates to chalcogenide nanomaterials, and more specifically to a method or process of synthesizing or preparing chalcogenide nanomaterials. Various example embodiments more particularly relate to metal chalcogenide nanomaterials, for example, to copper, lead and/or silver chalcogenide nanomaterials. In further specific examples, the chalcogenide nanomaterials are formed or provided as nanostructures, such as nanoparticles, nanowires, nanotubes and/or nanosheets. Such chalcogenide nanomaterials find application in, for example, conversion of heat and/or light into electricity.

### BACKGROUND

Growing energy demands, concerns over climate change and depleting fossil fuel resources have led to a concerted effort to efficiently use energy through advanced technologies, of which green thermoelectric (TE) and photovoltaic (PV) technologies have attracted considerable attention, because over 60% of energy produced is wasted as heat (see A. J. Simon and R. D. Belles, Lawrence Livermore National Labs, 2011, LLNL-MI-410527), and solar energy is abundant and sustainable.

Direct conversion of huge amounts of waste heat into electricity would significantly relieve energy and environmental issues. However, a major drawback of current TE technology is the low conversion efficiency (typically ˜5%) due to the lack of high-performance TE materials. The performance of TE materials is characterized by a dimensionless parameter of merit (ZT) according to the equation:

$$Z = \frac{{S}^{2} σ}{κ} \qquad ( 1 )$$

where S, σ, T and κ are the Seebeck coefficient, electrical conductivity, absolute temperature, and thermal conductivity, respectively.

Equation 1 clearly shows that the key to achieving a high ZT is to increase electrical conductivity and Seebeck coefficient, while reducing thermal conductivity. However, achieving this is very challenging for bulk thermoelectric materials because these parameters are interdependent and so changing one alters the others (see Z. Li, Q. Sun, X. D. Yao, Z. H. Zhu and G. Q. Lu, J. Mater. Chem., 2012, 22, 22821-22831.)

In recent years, significant progress has been made in improving the ZT of various TE materials by application of nanotechnology. Improvement of thermoelectric performance arising from nano effects are mainly due to a decrease in the thermal conductivity arising from increased phonon scattering and quantum confinement effects. One example is lead telluride (PbTe), which has been known for several decades with the best reported ZT being 1 at 750 K, whereas after introduction of nanoprecipitates by chemical doping (e.g. Sr- and Na-codoped PbTe, Ag- and Sb-codoped PbTe) the ZT has been improved to 2.2 at 915 K (see K. Biswas, J. He, I. D. Blum, C.-I. Wu, T. P. Hogan, D. N. Seidman, V. P. Dravid and M. G. Kanatzidis, Nature, 2012, 489, 414-418.) The lead telluride (PbTe) analogues of lead sulfide (PbS) and lead selenide (PbSe) also show a ZT over 1 or approaching 2 after introduction of nanoprecipitates, e.g. the nanocomposites of PbS—Bi₂S₃ (or Sb₂S₃, SrS and CaS) exhibit a ZT of 1.3 at 923 K.

However, these lead chalcogenide nanocomposites were prepared through solid state reactions at high temperature under vacuum, following a quenching process. Similarly, copper- and silver-based chalcogenides are promising in thermoelectrics and can be prepared by solid state reactions at high temperature. For example, cuprous selenide (Cu₂₋ₓSe) prepared at 1050° C. has a high ZT of 1.6 at 1000 K (see H. Liu, X. Shi, F. Xu, l. Zhang, W. Zhang, L. Chen, Q. Li, C. Uher, T. Day and G. J. Snyder, Nat. Mater., 2012, 11, 422-425.) This value has been further improved to 1.7˜1.8 at 973 K by using advanced fast quenching approach, which could result in nanoprecipitates and a high density (L. L. Zhao, X. L. Wang, J. Y. Wang, Z. X. Cheng, S. X. Dou, J. Wang, L. Q. Liu, Sci. Rep. 2015, 5, 7671(1-6)).

In addition to nanocomposites generated from solid state reactions, there are some reports on the thermoelectric properties of solution-processed metal chalcogenide nanostructures such as nanoparticles and nanowires. These nanostructures are either prepared by a solvothermal approach at high temperature under protection of an inert atmosphere, or by a hydrothermal approach in sealed reactors such as autoclaves. Therefore, such nanocomposites are not suitable for practical application due to a complicated preparation process being required and associated high cost.

Another potential application of metal chalcogenide nanomaterials is in solar cells which can directly convert energy of light into electricity. For example, nanostructured lead chalcogenides can be used to fabricate quantum dots sensitized solar cells (QDSSCs) to achieve high conversion efficiency (see Z. Ning, et al., Nat. Mater. 2014, 13, 822; C. H. Chuang, P. R. Brown, V. Bulovic, M. G. Bawendi, Nat. Mater. 2014, 13, 796). Copper chalcogenides can serve as excellent counter electrodes of QDSSCs where polysulfide electrolytes are used with enhanced electrochemical performance owing to their super catalytic activity for the reduction of polysulfide (see Z. S. Yang, et al., Adv. Energy Mater. 2011, 1, 259; Y. Jiang, et al., Nano. Lett. 2014, 14, 365). They show lower resistance and higher electrocatalytic activity towards the redox reaction of polysulfide, in comparison with the conventional noble counter electrodes (Pt or Au) which can be passivated by sulfur-containing (S²⁻ or thiol) compounds. However, most metal chalcogenide nanostructures are made from complicated processes such as solvo/hydrothermal approaches.

There is a need for new or improved chalcogenide nanomaterials and/or new or improved methods or processes of synthesizing or preparing chalcogenide nanomaterials.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### SUMMARY

This Summary is provided to introduce a selection of concepts in a simplified form that are further described below in the Preferred Embodiments. This Summary is not intended to identify key features or essential features of the claimed subject matter, nor is it intended to be used to limit the scope of the claimed subject matter.

In one aspect there is provided a chalcogenide nanomaterial. In another aspect there is provided a metal chalcogenide nanomaterial, for example, a copper, lead and/or silver chalcogenide nanomaterial. In another aspect there is provided a method or process of synthesizing or preparing a chalcogenide nanomaterial, preferably a metal chalcogenide nanomaterial.

In accordance with another example aspect, there is provided a liquid-based chemical method to prepare metal chalcogenide nanomaterials, preferably in a solvent and in the presence of one or more ligands, preferably one or more organic ligands. That is, the mixture undergoing reaction is a liquid mixture. Also preferably, heat is applied at a reaction temperature. For example, the reaction temperature preferably ranges from about 0° C. to about 200° C., inclusively. More preferably, the reaction temperature is between about 10° C. to about 80° C., inclusively. Even more preferably, the reaction temperature is between about 20° C. to about 60° C., inclusively. The reaction temperature could also be about room temperature.

An example method for producing metal chalcogenide nanomaterial comprises the steps of: forming a mixture (for example by mixing, adding, combining, agitating or stirring) of a metal precursor, a chalcogen-based ligand, a solvent and a chalcogen precursor, in a reaction vessel; heating the mixture at a reaction temperature for a duration of reaction time; and, separating a product (i.e. a produced metal chalcogenide nanomaterial). Preferably, the metal precursor is a pure metal or a metal oxide.

Another example method for producing metal chalcogenide nanomaterial comprises the steps of: (i) mixing a metal precursor with a chalcogen-based ligand; (ii) adding a solvent; (iii) adding a chalcogen precursor; (iv) heating the mixture at a reaction temperature for a duration of reaction time; and (v) separating a product (i.e. a produced metal chalcogenide nanomaterial). Steps (i) to (iv) may be performed sequentially, in different orders of the steps, or some or all of the steps (i) to (iv) may be performed contemporaneously (i.e. simultaneously).

Reference to a chalcogen-based ligand should be read as generally referring to a ligand that includes or contains one or more chalcogens, or in other words a chalcogen-containing ligand. The chalcogen-based ligand is preferably a chalcogen-based organic ligand.

In further non-limiting examples, the method involves the preparation of copper (Cu) based, lead (Pb) based, and/or silver (Ag) based chalcogenide nanomaterials. In accordance with another example aspect, there is provided a chalcogenide nanomaterial of formula M₂₋ₓE where M is Cu, Pb or Ag; E is S, Se or Te; and x is between 0 and 1, inclusively (i.e. 0≤x≤1).

In further specific examples, the chalcogenide nanomaterials are formed or provided as nanostructures, such as for example nanoparticles, nanowires, nanotubes and/or nanosheets.

### BRIEF DESCRIPTION OF FIGURES

Example embodiments are apparent from the following description, which is given by way of example only, of at least one preferred but non-limiting embodiment, described in connection with the accompanying figures.

FIG. 1 illustrates an example method for synthesis of metal chalcogenide nanomaterials, demonstrated by the preparation of copper selenide from selenium powder and copper or copper oxide precursors. The copper precursor can be newly synthesized or commercial powder.

FIG. 2a is a scanning electron microscope (SEM) image of Cu nanowires synthesized according to the example method illustrated in FIG. 1. FIGS. 2b and 2c are SEM and transmission electron microscope (TEM) images of architectured Cu₂₋ₓSe nanotubes made from as-synthesized Cu nanowires and Se powder. FIG. 2d is x-ray diffraction (XRD) patterns of Cu nanowires and Cu₂₋ₓSe nanotubes, proving the successful conversion of Cu nanowires into Cu₂₋ₓSe nanotubes at relatively low temperature.

FIGS. 3a, 3b and 3c are SEM images of Cu₂₋ₓSe nanotubes obtained at different reaction times, showing the evolution of Cu₂₋ₓSe nanotubes for a fast reaction time, and FIG. 3d shows x-ray diffraction (XRD) patterns at different reaction times.

FIG. 4 shows SEM images of Cu₂₋ₓSe nanostructures prepared from different ratios of Cu nanowires and sulfur-containing ligands, demonstrating that the morphology of Cu₂₋ₓSe nanomaterials can be effectively tuned by a metal precursor/ligand ratio.

FIG. 5 shows SEM images of Cu₂₋ₓSe nanostructures prepared in the presence of different sulfur-containing ligands, demonstrating the pronounced effects of ligands on the morphology of Cu₂₋ₓSe nanostructures.

FIGS. 6a-b are SEM images of Cu₂₋ₓSe nanostructures prepared in different solvents, FIGS. 6c-f are SEM images of synthesized CuO powder precursor, CuSe nanoparticle product, commercial Cu powder precursor and an example produced Cu₂₋ₓSe nanoparticles, demonstrating the broad options for precursors, solvents and tunable structures.

FIG. 7 shows SEM images of Cu₂₋ₓS, Cu₂₋ₓTe, PbSe, and Ag₂Se nanostructures prepared by a similar method as used to produce the Cu₂₋ₓSe nanostructures. The precursors for PbSe and Ag₂Se are commercial PbO powder and synthesized Ag nanowires, respectively.

FIG. 8 shows the electrical conductivity, Seebeck coefficient and thermal conductivity of Cu₂₋ₓSe pallet, made from Cu₂₋ₓSe nanoparticles produced in a temperature range of 300-1000 K, using spark plasma sintering (SPS) at a temperature of 430° C. for a duration of 10 min under a pressure of 65 MPa, demonstrating excellent thermoelectric performance.

FIG. 9 shows the performance of quantum dots sensitized solar cells (QDSSCs) by using copper chalcogenide nanotubes as counter electrodes, demonstrating the higher electrocatalytic activity towards the redox reaction of polysulfide, in comparison with Au counter electrodes.

FIG. 10 shows an example method for producing metal chalcogenide nanomaterial.

### PREFERRED EMBODIMENTS

The following modes, given by way of example only, are described in order to provide a more precise understanding of the subject matter of a preferred embodiment or embodiments. In the figures, incorporated to illustrate features of an example embodiment, like reference numerals are used to identify like parts throughout the figures.

In a general example there is provided a chalcogenide nanomaterial, more preferably a metal chalcogenide nanomaterial, for example, a copper (Cu), lead (Pb) and/or silver (Ag) chalcogenide nanomaterial. A novel method or process of synthesizing or preparing the chalcogenide nanomaterial or the metal chalcogenide nanomaterial is described. There is also described a liquid-based, i.e. wet-chemical, method to prepare metal chalcogenide nanomaterials, preferably in a solvent and in the presence of one or more organic ligands, i.e. the reacting mixture is a liquid mixture. Preferably, a reaction temperature of the method or process is performed at a temperature, for example between about 0° C. to about 200° C., inclusively, or the reaction temperature is between about 10° C. to about 80° C., inclusively, or the reaction temperature is between about 20° C. to about 60° C., inclusively, or the reaction temperature is about room temperature. Embodiments of the method involve the preparation of copper based, lead based, and/or silver based chalcogenide nanomaterials of formula M₂₋ₓE where M is Cu, Pb and/or Ag; E is S, Se and/or Te; and x is between 0 and 1, inclusively (i.e. 0≤x≤1).

The chalcogenide nanomaterials are formed or provided as nanostructures, and can be provided in a variety of one-dimensional, two-dimensional and/or three-dimensional shapes or geometries, such as nanoparticles, nanowires, nanotubes and/or nanosheets. The method is a cost-effective approach for preparing chalcogenide nanomaterials, preferably metal chalcogenide nanomaterials that can be used for energy conversion. A method for producing metal chalcogenide nanomaterial comprises the steps of: forming a mixture of, for example by mixing, stirring, adding, agitating, or otherwise combining, a metal precursor, a chalcogen-based ligand, a solvent and a chalcogen precursor, in a reaction vessel (for example any type of glassware, inert vessel, or alternatives); heating the mixture at a reaction temperature for a duration of reaction time, for example by heating in any form of heating equipment including an oven, burner, heating plate or mantle, steam oil, sand bath or hot air gun; and, separating a product (i.e. a produced metal chalcogenide nanomaterial).

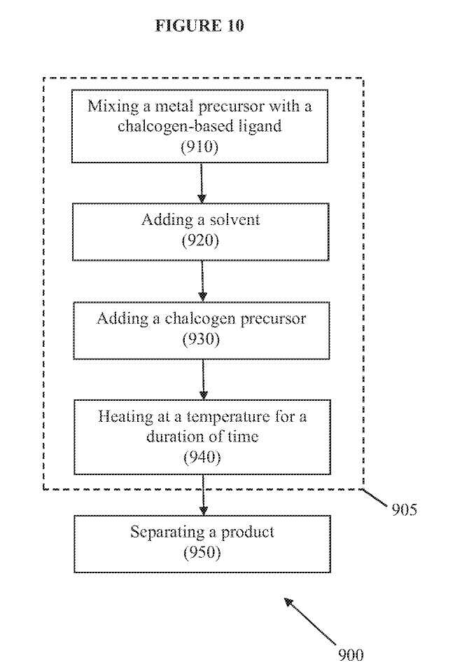

Referring to FIG. 10, an example method 900 for producing metal chalcogenide nanomaterials includes the steps of:
(i) Mixing a metal precursor with a chalcogen-based ligand in a reaction vessel (at step 910);
(ii) Adding a solvent to the reaction vessel (at step 920);
(iii) Adding a chalcogen precursor to the reaction vessel (at step 930);
(iv) Heating the mixture at a reaction temperature for a duration of reaction time in the reaction vessel (at step 940); and
(v) Separating or collecting a produced metal chalcogenide nanomaterial (at step 950).

It is possible to perform step 910 to step 930 sequentially or in any order. Furthermore, it is possible to perform steps 910, 920 and 930 contemporaneously or simultaneously. Steps 910, 920, 930 and 940 may be characterised as a single or consolidated step 905 of: forming a mixture of a metal precursor, a chalcogen-based ligand, a solvent and a chalcogen precursor, and heating the mixture at a reaction temperature for a duration of reaction time.

In examples, the metal precursor can be a pure metal powder or a metal oxide powder. Also for example, the chalcogen-based ligand can be a chalcogen-based organic ligand. Also for example, the chalcogen precursor can be a chalcogen itself, a chalcogen powder, a chalcogen solution, a chalcogen-based powder or compound, or a chalcogen-based solution, where the chalcogen is sulfur, selenium, tellurium or mixtures thereof. Also for example, the reaction temperature can be in a range of between and including from about 0° C. to about 200° C., from about 10° C. to about 80° C., from about 20° C. to about 60° C., inclusively. Also for example, the duration of the reaction time can be in a range of between and including about 1 min to about 72 hours, or from about 1 min to about 24 hours, or from about 1 min to about 12 hours, or from about 1 min to about 1 hour, or from about 1 min to about 5 min. Also for example, the product is collected by centrifugation or solvent precipitation, and in a further example can be dried under vacuum to a constant weight.

According to a further example method for producing metal chalcogenide nanomaterial, the method includes the steps of:
(i) Mixing a metal precursor with sulfur-containing ligands in a reaction vessel. The cationic precursors can be freshly prepared or commercial nano- or micro-powders;
(ii) Adding one or more alcohols and/or ketone as a solvent;
(iii) Adding a chalcogen precursor as a chalcogen powder or a chalcogen solution into the mixture;
(iv) Heating the mixture at a reaction temperature for a duration of reaction time;
(v) Separating or collecting a produced metal chalcogenide nanomaterial, for example by centrifugation or solvent precipitation, and drying under vacuum to a constant weight.

Advantageously, the reactants, solvents and ligands can be selected from multiple resources, are provided to form a liquid mixture, and the resultant chalcogenide nanomaterials are tunable in size, shape, geometry, composition and/or crystallinity. It is not necessarily the case that steps (i) to (iv) need to be performed sequentially, and steps (i) to (iv) may be performed contemporaneously.

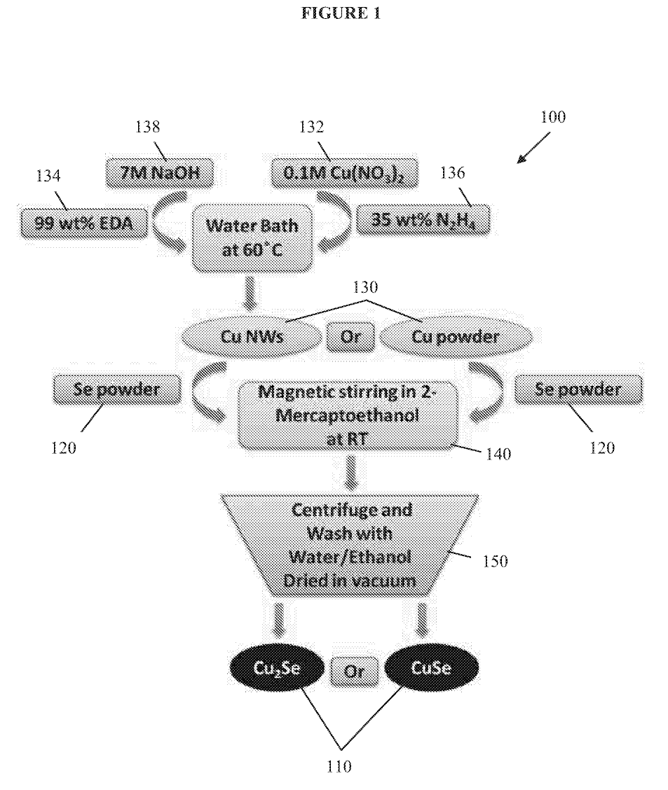

FIG. 1 illustrates an example method 100 for synthesis of metal chalcogenide nanomaterials, demonstrated by the preparation of copper selenide nanomaterials 110 from selenium powder 120 (i.e. a chalcogen precursor) and copper or copper oxide precursors 130 (i.e. a metal precursor). The copper precursor 130 can be newly synthesized or commercial copper powder. In this example, the copper precursor 130 was freshly prepared by reduction of copper nitrate 132 using ethylenediamine (EDA) 134 and hydrazine 136 in sodium hydroxide solution 138. The copper powder was formed as copper nanowires or nanoparticles (i.e. copper precursor 130) and was then mixed at room temperature (i.e. about 20° C.) with 2-mercaptoethanol (i.e. a chalcogen-based ligand), followed by addition of ethanol (i.e. a solvent) and addition of selenium powder (i.e. the chalcogen precursor), at step 140. This mixture was mixed, e.g. stiffed, at room temperature (i.e. heated at about 20° C.) for about 1 hour, and about 12 hours, and preferably about 24 hours in a reaction vessel, e.g. an inert container or glassware. The resultant copper selenide nanomaterials 110 were separated at step 150 by centrifugation and washed with ethanol for a few times. The purified copper selenide nanomaterials 110 were dried under vacuum. This provides a specific example method for producing metal chalcogenide nanomaterial comprising the steps of: forming a mixture of a metal precursor, a chalcogen-based ligand, a solvent and a chalcogen precursor; heating the mixture at a reaction temperature for a duration of reaction time; and, separating a produced metal chalcogenide nanomaterial.

Metal chalcogenides are premiere mid-range thermoelectric materials and their performance can be significantly enhanced when in the form of nanomaterials, for example as nanostructures, as metal chalcogenide nanomaterials can drastically reduce thermal conductivity. The results described below demonstrate examples that can be used to prepare metal chalcogenide nanomaterials, for example that can be used for conversion of heat into electricity.

Metal chalcogenide nanomaterials were prepared by the reaction of a metal precursor, for example a pure metal and/or a metal oxide as a metal precursor, with a chalcogen precursor (which can be a pure chalcogen itself such as sulfur, selenium, tellurium or mixtures thereof) in the presence of chalcogen-containing or chalcogen-based (e.g. sulfur-containing or sulfur-based) ligands, which can be organic ligands, in a solvent or mixture of solvents, which may be common solvent(s). Typically, freshly prepared (or commercial) metal or metal oxide powder was mixed with sulfur-containing ligands in a round flask (i.e. a reaction vessel), followed by addition of the solvent. Then chalcogen powder or a chalcogen in solution was added into the flask (i.e. reaction vessel). The resultant mixture was heated and stirred at a set reaction temperature for a duration of reaction time. The reaction temperature and reaction time are strongly dependent on the precursor type and size. The resultant nanomaterials were separated/collected by centrifugation after being precipitated with solvents, and then washed with solvent to remove impurities. The final product was dried under vacuum.

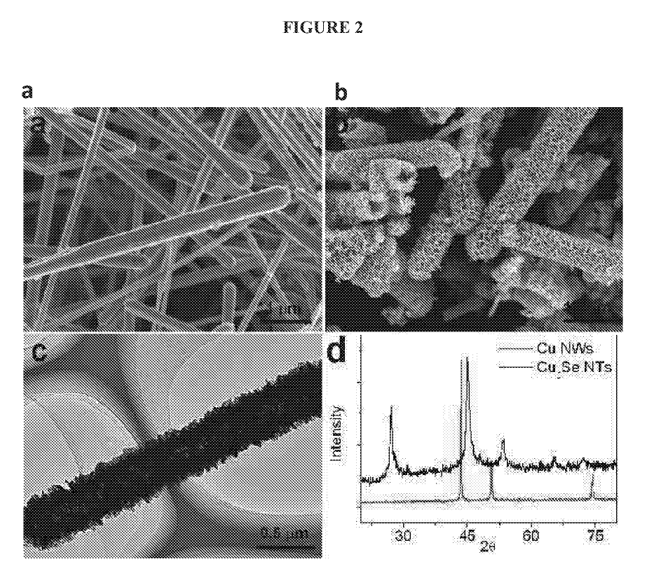

FIG. 2a shows an SEM image of 200-nm Cu nanowires which were freshly prepared and used as metal precursor. FIGS. 2b-c show the product SEM and TEM images after Cu nanowires reacted with Se powder in the presence of 2-mercaptoethanol in ethanol, clearly showing a tubular morphology. In addition, the surface of nanotubes is decorated with nanosheets. The XRD patterns displayed in FIG. 2d confirmed the transformation of Cu nanowires (NWs) into Cu₂₋ₓSe nanotubes (NTs) through self-sacrifice of Cu nanowires.

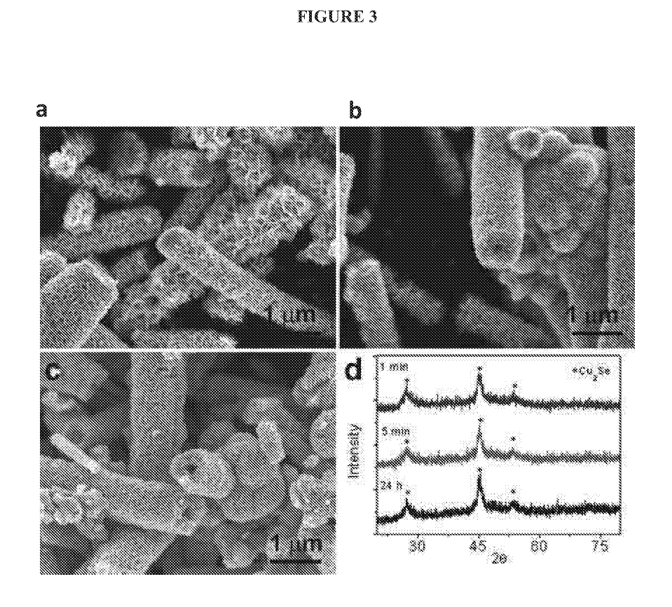

In order to understand the formation mechanism, the Applicant investigated the evolution of nanotubes against reaction time. FIGS. 3a-c show the SEM images of products obtained from 1 min, 5 min and 24 h reaction times, respectively, and FIG. 3d shows the corresponding XRD patterns. The results clearly show that nanosheets formed on the nanowire surface first and then the hollow structure formed through diffusion. The results also demonstrate that the formation of nanotubes was completed within a few minutes, which is much faster than previously known methods and demonstrates the fast reaction involved in the present method.

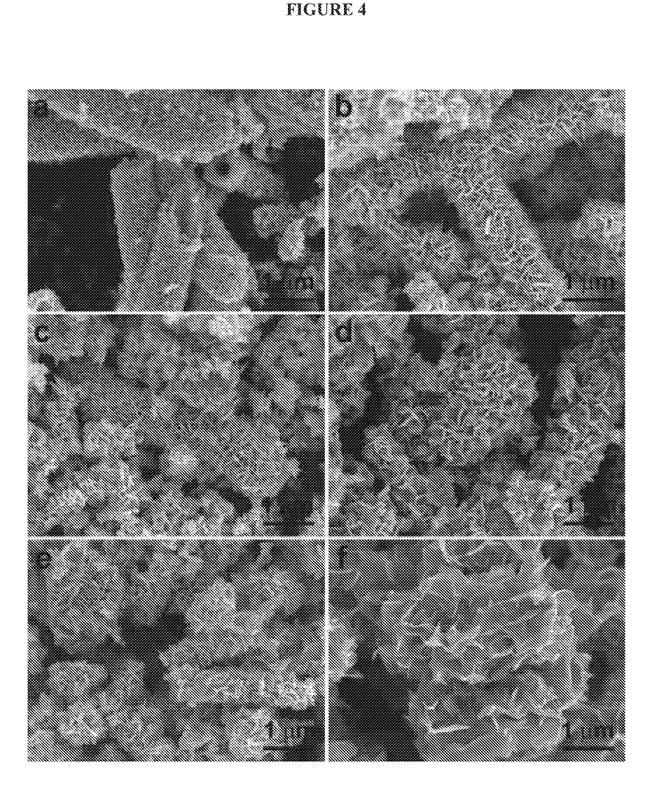

In the present embodiments, the chalcogen-based (e.g. sulfur-based) ligands play a crucial role in the formation of metal chalcogenide nanomaterials, and the influence of the ratio of the chalcogen-based ligands to the metal precursor has been studied by the Applicant. FIGS. 4a-f are the SEM images of Cu₂₋ₓSe nanostructures obtained from Cu nanowires in the presence of 2-mercaptoethanol with a molar ratio of (metal precursor:chalcogen-based ligands) 1:3, 1:10, 1:20, 1:30, 1:50 and 1:500, respectively. It clearly shows the gradual decrease in nanotube morphology with the molar ratio of Cu-precursor to 2-mercaptoethanol changing from 1:3 to 1:500, accompanied by the increase in nanosheets due to the transformation of nanotubes into nanosheets.

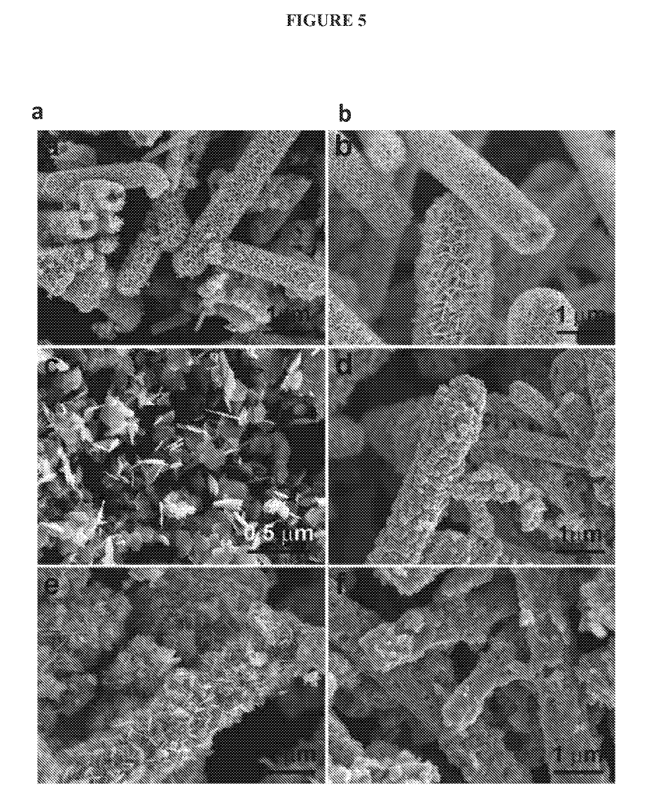

The influence of ligand molecular structure has been also investigated by the Applicant. FIGS. 5a-f provide SEM images of samples prepared in the presence of some typical sulfur-containing ligands (i.e. example chalcogen-based ligands), such as 2-mercaptoethanol, cysteamine, 3-mercaptopropanoic acid, thiolactic acid, thioacetamide and thiourea, respectively. The results demonstrate a strong dependence of nanostructures on the ligands.

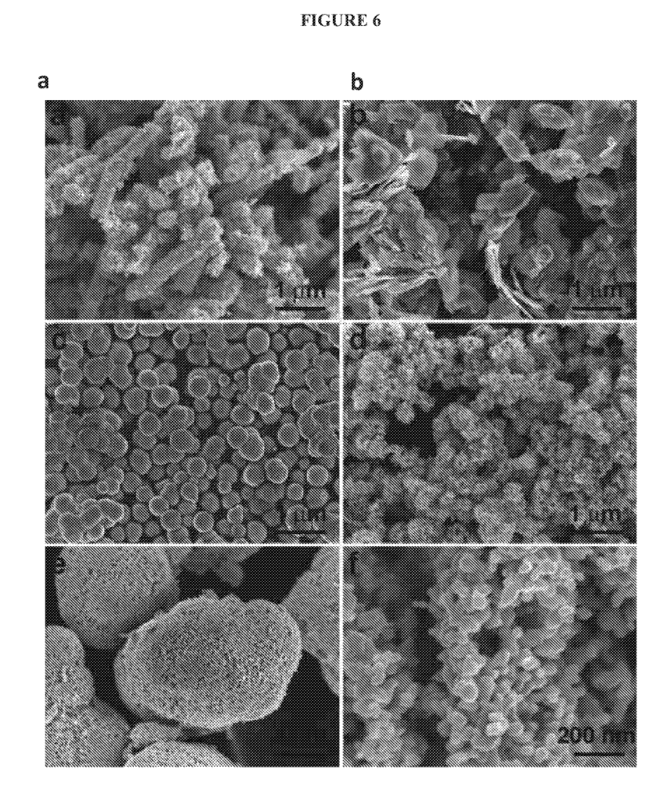

It should be noted that the solvent also influences the formation of nanostructures. FIGS. 6a-b show the SEM images of Cu₂₋ₓSe nanostructures synthesized in methanol and acetone, which are different to that produced in ethanol. In addition to Cu nanowires, micro-sized Cu balls and CuO powder can be used as a metal precursor. FIGS. 6c-f show the SEM images of (c) synthesized CuO powder and its resultant (d) hollow CuSe nanoballs, (e) commercial micro-sized Cu particles and (f) the resultant Cu₂₋ₓSe nanoparticles. It is very interesting that use of pure 2-mercaptoethanol rather than its mixture with ethanol resulted in Cu₂₋ₓSe nanoparticles not CuSe nanoparticles, which means the nanoparticle composition and crystal structure can be tuned by the molar ratio of ligands to solvent.

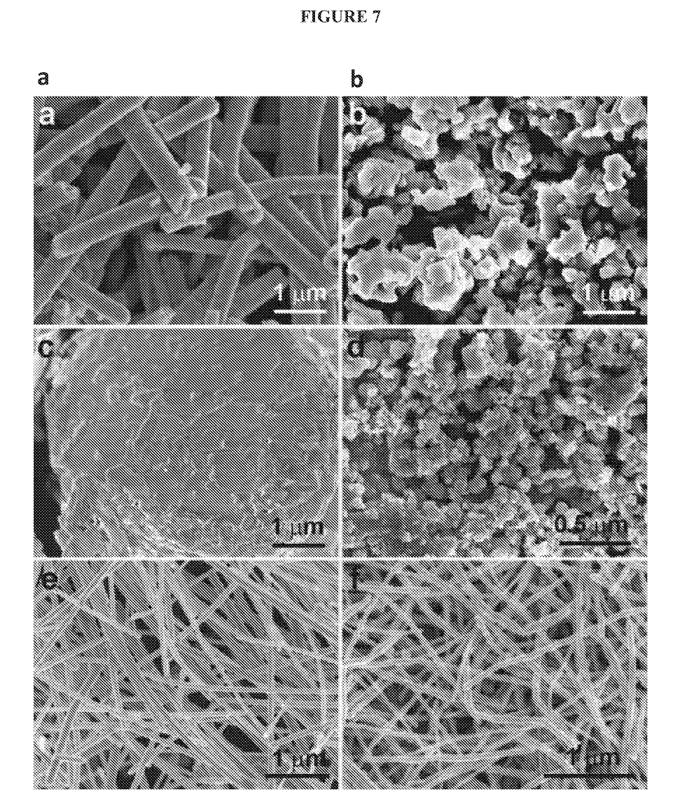

An important aspect of the present approach is its applicability, and the present method can be used to prepare other metal chalcogenide nanostructures with broad options for precursors. FIGS. 7a-b show the SEM images of Cu₂₋ₓS nanotubes and Cu₂₋ₓTe nanoparticles prepared from Cu nanowires, FIGS. 7d and 7f are SEM images of PbSe nanoparticles and Ag₂Se nanowires prepared from commercial PbO powder and synthesized Ag nanowires (FIGS. 7c and 7e), respectively.

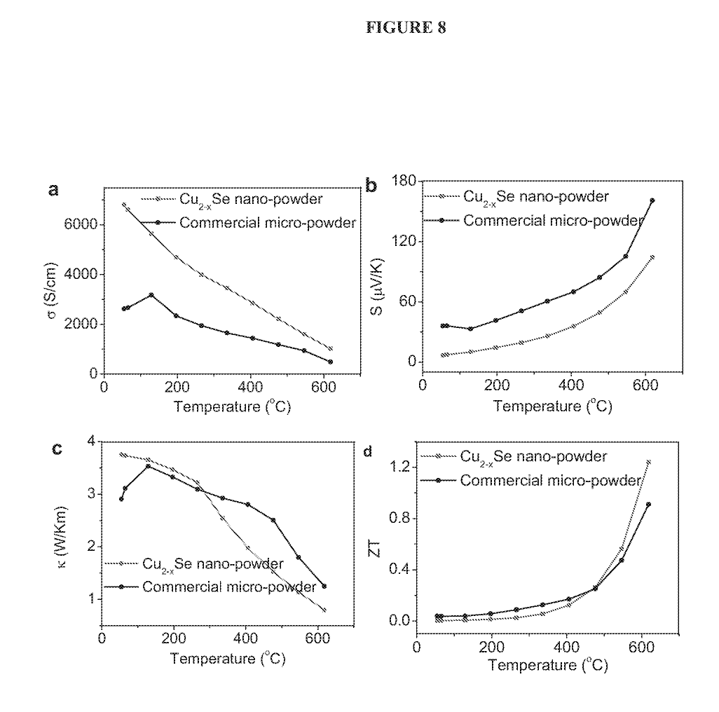

The resultant metal chalcogenide nanostructures have great potential in conversion of light or heat into electricity. FIG. 8 depicts the fundamental thermoelectric properties of Cu₂₋ₓSe nanoparticles after being sintered by spark plasma sintering at 430° C. In comparison with commercial Cu₂₋ₓSe powder, the thermoelectric performance of Cu₂₋ₓSe nanoparticles has been pronouncedly enhanced due to the decrease in thermal conductivity arising from, it is believed, improved phonon scattering.

In another example, there is provided a method of synthesizing metal chalcogenide nanomaterials by using a metal (e.g. Cu, Pb and/or Ag) and/or a metal oxide (e.g. Cu₂O, CuO, PbO and/or Ag₂O) powder, or any other physical form, as a precursor material. The metal or metal oxide can be freshly prepared powders or commercially prepared powders. Preferably, the powders include nano-scale or micro-scale particles, wires or sheets. The metal precursor can be formed of pure metal or metal oxide nanoparticles, nanowires or nanosheets.

In another example, there is provided a method of synthesizing metal chalcogenide nanomaterials, including the step of utilizing S, Se and/or Te as a precursor material. Preferably, though not necessarily, these materials are in powder form. They can be also dissolved in organic solvents such as alkyl phosphine ([CH₃(CH₂)ₙ]₃P, n=0-7) and alkylamine [CH₃(CH₂)ₙNH₂, n=0-17].

In another example, there is provided a method of synthesizing metal chalcogenide nanomaterials by utilizing sulfur-containing organic compounds as ligands (i.e. chalcogen-based ligands). The nanostructure size and morphology can be tuned by the ratio between precursor and ligands. In another example, chalcogen powder is used as anionic-precursor. In another example, chalcogen-based solution is used as anionic-precursor. Chalcogen solution can be made by dissolving chalcogen powder in alkyl phosphine [(R)₃P, R=butyl, octyl], or liquid alkylamine such as oleyamine.

In another example, there is provided a method of synthesizing metal chalcogenide nanomaterials by using monothiols [CH₃(CH₂)ₙ—SH, n=0-10], dithiols [HSCH₂—(CH₂)ₙ—CH₂SH, n=0-6], and/or multithiols [HSCH₂—(CHSH)ₙ₁—CH₂SH, n₁=1-4] as ligands, where the SH position is variable. In another example, there is provided a method of synthesizing metal chalcogenide nanomaterials by using monornereapto-substituted primary, secondary and tertiary monohydric alcohols as ligands. Example molecular structures are presented in Scheme 1.
Primary alcohols: HSCH₂(CH₂)ₙ—OH, n=1-10; HS-PEG-OH, PEG is poly(ethylene glycol) with an average molecule weight smaller than 5000)
Secondary alcohols: HSCH₂CHOH—(CH₂)ₙCH₃, n=1-10 and —OH position is variable
Tertiary alcohols: HSCH₂CROH—(CH₂)ₙCH₃, n=1-10, R=methyl, ethyl and propyl, the position of —OH and R groups is variable
   Scheme 1. Monomercapto-substituted monohydric alcohols

In another example, there is provided a method of synthesizing metal chalcogenide nanomaterials by using monomercapto-substituted polyhydric alcohols (examples are presented in Scheme 2) as ligands, such as thioglycerol, mercapto-substituted butanediol, mercapto-substituted pentadiol and/or thiopentaerythritol.

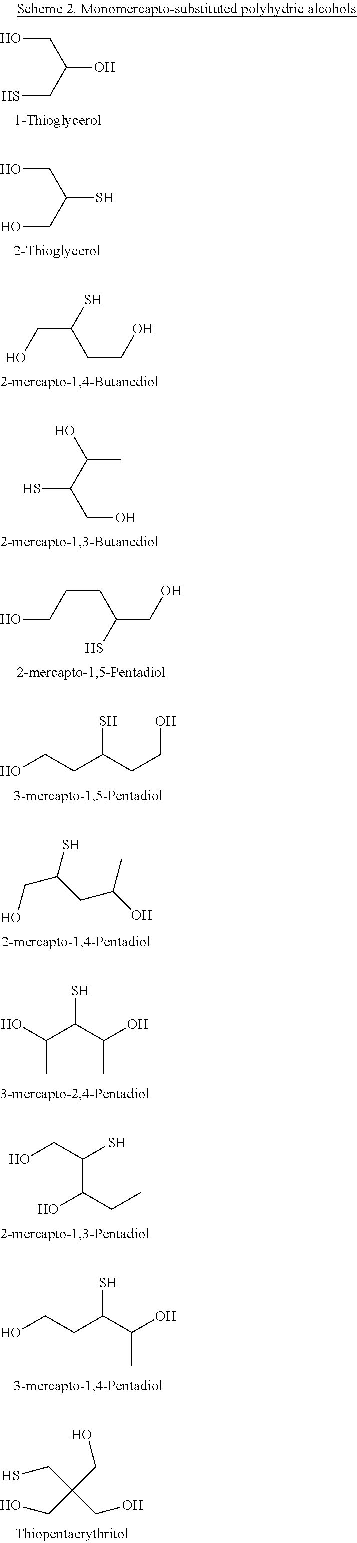

In another example, there is provided a method of synthesizing metal chalcogenide nanomaterials by using dimercapto-substituted monohydric or polyhydric alcohols (examples are presented in Scheme 3) as ligands, such as dimercaptopropanol, dimercaptobutanol, and/or dimercaptobutanediol.

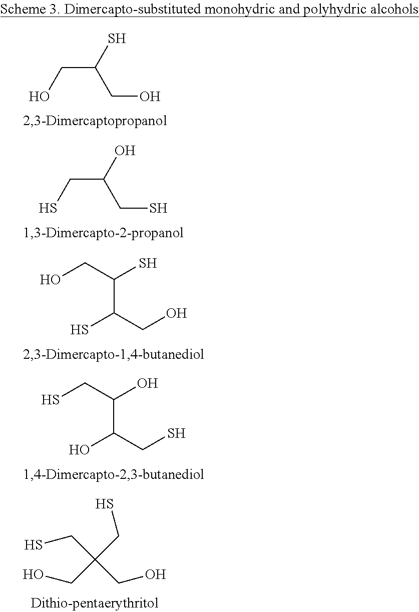 [SMILES: OCC(S)CO ; OC(CS)CS ; OCC(S)C(S)CO ; OC(CS)C(O)CS ; OCC(CO)(CS)CS]

In another example, there is provided a method of synthesizing metal chalcogenide nanomaterials by using mercapto-substituted primary, secondary and tertiary amines and/or imides as ligands (examples are presented in Scheme 4).
Primary amines: HSCH₂(CH₂)ₙ—NH₂, n=1-10 and —SH position is variable; HS-PEG-NH₂, PEG is poly(ethylene glycol) with an average molecule weight between 200 and 5000)
Secondary amines: HSCH₂(CH₂)ₙNHR, n=1-10, R is alkyl group and —SH position is variable
Tertiary alcohols: HSCH₂(CH₂)ₙNR₁R₂, n=1-10, R₁ and R₂ are alkyl groups, and —SH position is variable
Primary imides: HSCH₂(CH₂)ₙ—CONH₂, n=0-10 and —SH position is variable; HS-PEG-CONH₂, PEG is poly(ethylene glycol) with an average molecule weight between 200 and 5000)
Secondary imides: HSCH₂(CH₂)ₙCONHR, n=0-10, R is alkyl group and —SH position is variable
Tertiary imides: HSCH₂(CH₂)CONR₁R₂, n=0-10, R₁ and R₂ are alkyl groups, and —SH position is variable
Scheme 4. Monomercapto-substituted primary, secondary and tertiary amines and imides.

In another example, there is provided a method of synthesizing metal chalcogenide nanomaterials by using mercapto-substituted acids [HS(CH₂)ₙCOOH, n=0-10 and —SH position is variable] as ligands. In another example, there is provided a method of synthesizing metal chalcogenide nanomaterials by using thioacetic acid (CH₃COSH), thiourea (H₂NCSNH₂), and/or thioamide (R₁CSNR₂R₃, R₁=methyl, ethyl, propyl, R_{2,3}=hydrogen, methyl, ethyl, propyl) as ligands.

In another example, there is provided a method of synthesizing metal chalcogenide nanomaterials with additional reactive groups of —SH, —OH, —NH₂ and/or —COOH being added to the reacting mixture for further functionalization and modification.

In another example, there is provided a method of synthesizing metal chalcogenide nanomaterials by utilizing monohydric alcohols including primary alcohol [CH₃(CH₂)ₙ—OH, n=0-10], secondary alcohol [CH₃CH(OH)(CH₂)ₙCH₃, n=0-4] and/or tertiary alcohol [(CH₃)₂C(OH)(CH₂)ₙCH₃, n=0-4], or polyhydric alcohols [(CH₂OH)(CHOH)ₙ(CH₂OH), n=0-4; HO—(CH₂CH₂O)ₙ—H, n=1-20] as a solvent. That is, the solvent can be one or more alcohols. In another example, there is provided a method of synthesizing metal chalcogenide nanomaterials by utilizing symmetrical and/or asymmetrical ketones [R₁COR₂, R_{1,2}=methyl, ethyl, propyl] as a solvent.

In another example, there is provided a method of synthesizing metal chalcogenide nanomaterials in a temperature range of from about 0° C. to about 200° C., inclusively. Preferably, the reaction temperature is from about 10° C. to about 80° C., inclusively. More preferably, the reaction temperature is from about 20° C. to about 60° C., inclusively.

In another example, there is provided a method of preparing metal chalcogenide nanostructures within a reaction time ranging from about 1 minute to about 72 hours, inclusively, depending on the size of precursors, ligands, solvents and reaction temperature. Preferably, the reaction time is from about 1 minute to about 24 hours, or from about 1 mm to about 12 hours, or from about 1 min to about 1 hour, inclusively. The reaction time may also be from about 1 minute to about 5 minutes, inclusively.

In summary, embodiments of the present invention provide a general approach to prepare metal chalcogenide nanomaterials, preferably selected nanostructures, for example for energy applications, with tunable size and/or morphology by choosing from a wide range of precursors, ligands and solvents, as demonstrated by the following particular examples.

### FURTHER EXAMPLES

The following examples provide more detailed discussion of particular embodiments. The examples are intended to be merely illustrative and not limiting to the scope of the present invention.

### Example 1: Synthesis of Cu₂₋ₓSe Nanotubes from Cu Nanowires

Cu nanowires (i.e. a metal precursor) were prepared by reduction of Cu(NO₃)₂ with hydrazine in the presence of ethylenediamine (EDA) in a strong basic solution. In a typical synthesis, 3.0 mL of Cu(NO₃)₂ (1 M) solution was added into 90 mL of NaOH solution, followed by addition of 1.5 mL of EDA and 75 μL of hydrazine. The resultant mixture was heated to 60° C. and kept at this temperature for 1 hour. The formed copper nanowires were harvested by centrifugation, and then washed with water and acetone thoroughly. FIG. 2a shows the SEM image of obtained smooth Cu nanowires with an average diameter of 200 nm.

The as-synthesized Cu nanowires were used as metal precursor and transferred into a flask (i.e. a reaction vessel), and then mixed with 2-mercaptoethanol (i.e. a chalcogen-based ligand) and Se powder (i.e. a chalcogen precursor) with a ratio of 1:3:1 in ethanol (i.e. a solvent). The mixture was stirred at room temperature, that is about 20° C. (i.e. heating the mixture at the reaction temperature), for 24 hours (i.e. the duration of reaction time). The product was collected by centrifugation, washed with ethanol several times, and then dried under vacuum. FIGS. 2b-c shows the SEM and TEM images of the produced nanostructures, showing a tubular morphology and rough surface with nanosheets architecture. The XRD results (FIG. 2d) show the disappearance of Cu nanowires and the formation of Cu₂₋ₓSe nanotubes.

### Example 2: Preparation of Cu₂₋ₓSe Nanotubes from Different Reaction Time

The evolution of Cu₂₋ₓSe nanotubes was investigated by collecting samples at different reaction times. Cu nanowires and Cu₂₋ₓSe nanotubes were prepared by the same methods as stated above and samples were collected at 1 min, 5 min and 24 hours reaction times. The respective SEM images and XRD patterns in FIG. 3 clearly show the evolution of nanotubes. The reaction was almost completed at about 1 min, indicated by the absence of Cu nanowires in the SEM image (FIG. 3a) and XRD pattern (FIG. 3d). In addition, there are already some nanosheets formed on the surface of nanowires even after about 1 min, and their density increases with the increase of reaction time, accompanied by the transformation of solid nanowires into nanotubes (FIGS. 3b-c).

### Example 3: Synthesis of Cu₂₋ₓSe Nanostructures from Different Ratios of Cu-Precursor and Ligands

The size and morphology of Cu₂₋ₓSe nanostructures can be tuned by the molar ratio of Cu-precursor and the sulfur-containing organic ligands. In this group of experiments, Cu nanowires and 2-mercaptoethanol (i.e. a chalcogen-based ligand) were used as Cu-precursor (i.e. an example of a metal precursor) and ligands respectively. The preparation and purification procedures are the same as that described in Example 1. The molar ratio of Cu-nanowires and 2-mercaptoethanol was varied from 1:3 to 1:10, 1:20, 1:30, 1:50 and 1:500, and other reaction parameters were kept constant. The SEM images of resultant nanostructures are displayed in FIG. 4, which clearly shows a gradual decrease in nanotubes and increase in nanosheets with the molar ratio of Cu-nanowires/2-mercaptoethanol increasing from 1:3 to 1:10, 1:20, 1:30, 1:50 and 1:500.

### Example 4: Synthesis of Cu₂₋ₓSe Nanostructures from Different Sulfur-Containing Ligands

Cu₂₋ₓSe nanostructures stabilized with different sulfur-containing ligands were prepared by the same procedure of Example 1, except using different ligands to replace 2-mercaptoethanol, i.e. cysteamine, 3-mercaptopropanoic acid, thiolactic acid, thioacetamide and thiourea in this group of experiments. FIG. 5 compares the SEM images of resultant nanostructures with that of nanotubes prepared in the presence of 2-mercaptoethanol. The results demonstrate the strong dependence of nanostructures on the sulfur-containing ligands and their crucial role in the formation of Cu₂₋ₓSe nanostructures.

### Example 5: Synthesis of Cu₂₋ₓSe Nanostructures in Different Solvents

Cu₂₋ₓSe nanostructures can be prepared in solvents other than ethanol. Methanol and acetone were selected as representatives of alcohols and ketones. The preparation procedure is the same as that in Example 1. FIGS. 6a-b show the SEM images of products produced in methanol and acetone, demonstrating the influence of solvents on the nanostructure morphology.

### Example 6: Synthesis of Cu₂₋ₓSe Nanostructures from Different Copper Precursors

In addition to Cu nanowires, CuO nanoballs can be also used as Cu-precursors to prepare copper chalcogenide nanostructures. CuO nanoballs were prepared by a similar method as applied to Cu nanowires. Typically, 3.0 mL of Cu(NO₃)₂ (5 M) solution, 7.5 mL of EDA and 375 μL of hydrazine were sequentially added into 450 mL of NaOH solution. The mixture was then heated to 60° C. and kept at this temperature for 1 hour. The formed CuO nanoballs were collected by centrifugation, and then washed with water and acetone for a few times. The as-synthesized. CuO balls were mixed with 2-mercaptoethanol and Se powder in ethanol solution. The mixture was stirred for 24 hours and the resultant nanostructures were harvested and purified by centrifugation-redispersion for several times. FIGS. 6c-d show the SEM images of CuO nanoballs and CuSe nanostructure obtained, clearly showing transformation of CuO balls into hollow CuSe balls.

Commercial Cu powder was also used to replace Cu nanowires or CuO balls during the preparation of copper chalcogenide nanostructures. Cu, 2-mercaptoethanol and Se powder were loaded into a flask with a ratio of 1:3:1, then 10 mL of ethanol was added and the mixture was heated to 60° C. and stirred for 24 hours under this temperature. The product was collected by centrifugation and then washed with ethanol for a few times. The SEM images of Cu powder and the resultant copper selenide nanoparticles were presented in FIGS. 6e-f. Compared with Cu precursor, the size of resultant nanoparticles has been drastically reduced to around 40˜80 nm. It should be noted that the formation of CuSe or Cu₂₋ₓSe nanoparticles (i.e. the composition or the morphology of the produced metal chalcogenide nanomaterial) is strongly dependent on the amount of 2-mercaptoethanol (i.e. the amount of chalcogen-based ligand), i.e. use of less 2-mercaptoethanol led to CuSe and use of more 2-mercaptoethanol resulted in Cu₂₋ₓSe.

### Example 7: Synthesis of Cu₂₋ₓS and Cu₂₋ₓTe Nanostructures

Other copper chalcogenides such as Cu₂₋ₓS and Cu₂₋ₓTe nanostructures can be prepared by a similar procedure. The difference is the replacement of Se powder with S or Te. FIGS. 7a-b show the SEM image of Cu₂₋ₓS nanotubes and Cu₂₋ₓTe nanoparticles made from Cu nanowires, S powder and TOP-Te solution (TOP is trioctylphosphine). In contrast to Cu₂₋ₓe nanotubes, the Cu₂S nanotubes have a smooth surface.

### Example 8: Synthesis of Lead and Silver Chalcogenide Nanostructures

The synthesis of lead- and silver-chalcogenide nanostructures was demonstrated by using PbSe and Ag₂Se as examples. In a typical synthesis, commercial PbO (or Ag nanowires) powder was mixed with 2-mercaptoethanol and Se powder with a ratio of 1:3:1 in ethanol. The mixture was stirred for 24 hours. The reaction temperature for PbSe nanoparticles and Ag₂Se nanowires was about 60° C. and room temperature (˜20° C.), respectively. The product was collected by centrifugation, washed with ethanol for several times, and then dried under vacuum. FIGS. 7c-f show the SEM images of PbO powder and Ag nanowires, the obtained PbSe and Ag₂Se nanostructures. Their XRD patterns confirm the formation of pure PbSe and Ag₂Se nanostructures.

### Example 9: Thermoelectric Performance of Metal Chalcogenide Nanostructures

The thermoelectric properties of metal chalcogenide nanostructures were characterized using their pallets compressed from their nanostructure powder. Cu₂₋ₓSe pallet was made from nanoparticles as an example demonstration. Typically, 4.16 g of as-synthesized Cu₂₋ₓSe nanoparticles powder were loaded into 20-mm graphite die, and then densified at 430° C. for 10 min under argon atmosphere using a sparking plasma sintering technique. The pallet was then cut into pieces and the electrical conductivity and Seebeck coefficient were measured with an Ozawa RZ2001i (Japan) instrument, and the thermal conductivity was calculated from k=DCₚρ, where D is thermal diffusivity and measured by Netzsch LFA1000. Cₚ is the specific heat capacity and measured by differential scanning calorimetry and ρ is the density calculated from mass and volume. FIG. 8 shows the electrical conductivity, Seebeck coefficient, thermal conductivity, and ZT value of example Cu₂₋ₓSe pallet made from Cu₂₋ₓSe nanoparticles, in comparison with commercial. Cu₂₋ₓSe powder, demonstrating the better performance of the nanostructures produced according to an example embodiment of the present invention.

### Example 10: Fabrication of Counter Electrodes from Metal Chalcogenide Nanostructures

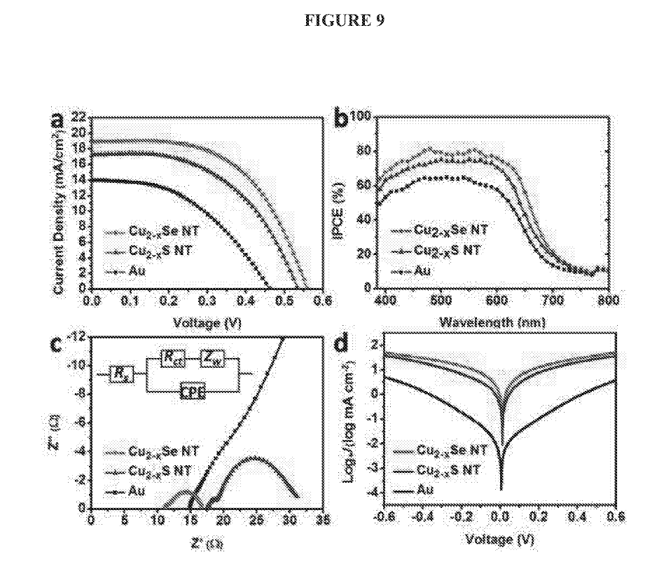

Another application of resultant metal chalcogenide nanostructures is in solar cells, serving as sensitizers and counter electrodes of quantum dots sensitized solar cells (QDSSCs). Cu₂₋ₓS and Cu₂₋ₓSe nanotubes were used to fabricate counter electrodes of QDSSCs. They were deposited on FTO substrates by the doctor blade technique and the formed films were annealed at 350° C. for 30 min in Ar atmosphere to remove the binder and enhance the contact between film and substrate. For comparison, Au electrodes were prepared by sputtering a layer of Au with 50 nm. FIG. 9 shows the performance of QDSSCs made with copper chalcogenide based counter electrodes, in comparison with that made from Au electrode.

Optional embodiments may also be said to broadly include the parts, elements, steps and/or features referred to or indicated herein, individually or in any combination of two or more of the parts, elements, steps and/or features, and wherein specific integers are mentioned which have known equivalents in the art to which the invention relates, such known equivalents are deemed to be incorporated herein as if individually set forth.

Although a preferred embodiment has been described in detail, it should be understood that many modifications, changes, substitutions or alterations will be apparent to those skilled in the art without departing from the scope of the present invention.

1. A method for producing metal chalcogenide nanomaterial, comprising the steps of:
forming a mixture of a metal precursor, where the metal precursor is a pure metal or a metal oxide, a chalcogen-based ligand, a solvent, and a chalcogen precursor;
heating the mixture at a reaction temperature between about 0° C. to about 200° C., inclusively, for a duration of reaction time; and,
separating a produced metal chalcogenide nanomaterial,
wherein, the produced metal chalcogenide nanomaterial is a copper, lead or silver chalcogenide nanomaterial.

2. The method of claim 1, wherein the produced metal chalcogenide nanomaterial has a formula of M₂₋ₓE, where:
M is Cu, Pb or Ag;
E is S, Se or Te; and
0≤x≤1.

3. The method of claim 1, wherein the reaction temperature is between about 10° C. to about 80° C., inclusively.

4. The method of claim 1, wherein the reaction temperature is between about 20° C. to about 60° C., inclusively.

5. The method of claim 1, wherein the reaction temperature is about room temperature.

6. The method of claim 1, wherein the duration of reaction time is from about 1 minute to about 72 hours, inclusively.

7. The method of claim 1, wherein the duration of reaction time is from about 1 minute to about 24 hours, inclusively.

8. The method of claim 1, wherein the duration of reaction time is from about 1 minute to about 12 hours, inclusively.

9. The method of claim 1, wherein the produced metal chalcogenide nanomaterial is formed as nanoparticles, nanowires, nanotubes and/or nanosheets.

10. The method of claim 1, wherein the mixture is a liquid mixture.

11. The method of claim 1, wherein the metal precursor is a copper, lead or silver precursor.

12. The method of claim 1, wherein the metal precursor is a powder.

13. The method of claim 1, wherein the metal precursor is formed of pure metal or metal oxide nanoparticles, nanowires or nanosheets.

14. The method of claim 1, wherein the chalcogen-based ligand is a chalcogen-based organic ligand.

15. The method of claim 1, wherein the chalcogen-based ligand is a sulfur-based ligand.

16. The method of claim 1, wherein the chalcogen-based ligand is a thiol or mercapto-substituted organic compound.

17. The method of claim 1, wherein the chalcogen-based ligand is a monothiol [CH₃(CH₂)ₙ—CH₂SH, n=0-16], dithiol [HSCH₂(CH₂)ₙ—CH₂SH, n=0-6] or multithiol [HSCH₂(CH₂)ₙ₁(CHSH)ₙ₂—CH₂SH, n₁=0-6; n₂=0-4], where a —SH position is variable.

18. The method of claim 1, wherein the chalcogen-based ligand is a mono-mercapto-substituted primary, secondary or tertiary monohydric alcohol.

19. The method of claim 1, wherein the chalcogen-based ligand is a mono-mercapto-substituted polyhydric alcohol.

20. The method of claim 1, wherein the chalcogen-based ligand is a dimercapto-substituted monohydric or polyhydric alcohol.

21. The method of claim 1, wherein the chalcogen-based ligand is a mercapto-substituted primary, secondary and tertiary amine or imide.

22. The method of claim 1, wherein the chalcogen-based ligand is a mercapto-substituted acid [HS(CH₂)ₙCOOH, n=0-10], where a SH position is variable.

23. The method of claim 1, wherein the chalcogen-based ligand is a thioacetic acid (CH₃COSH), thiourea (H₂NCSNH₂), or thioamide (R₁CSNR₂R₃, R₁=methyl, ethyl, propyl, R₂₃=hydrogen, methyl, ethyl, propyl).

24. The method of claim 1, wherein the chalcogen-based ligand is a multi-mercapto-substituted primary, secondary or tertiary alcohol, amine, acid or imide.

25. The method of claim 1, wherein the solvent is an organic solvent.

26. The method of claim 1, wherein the solvent is one or more alcohols.

27. The method of claim 1, wherein the solvent is ethanol, methanol or acetone.

28. The method of claim 1, wherein the solvent is a monohydric alcohol or primary alcohol [CH₃(CH₂)ₙ—OH, n=0-10; CH₃O—(CH₂CH₂O)ₙ—H, n=1-20], a secondary alcohol [CH₃(CHOH)(CH₂)ₙ—CH₃, n=0-10,] and/or a tertiary alcohol [(CH₃)₂(COH)(CH₂)ₙCH₃, n=0-10].

29. The method of claim 1, wherein the solvent is a polyhydric alcohol [HOCH₂(CHOH)ₙCH₂OH, n=0-4; HO—(CH₂CH₂O)ₙ—H, n=1-20].

30. The method of claim 1, wherein the solvent is a symmetric or an asymmetric ketone [R₁COR₂, R_{1,2}=methyl, ethyl and propyl].

31. The method of claim 1, wherein the chalcogen precursor is a chalcogen, a chalcogen powder, a chalcogen solution, a chalcogen-based powder or a chalcogen-based solution.

32. The method of claim 1, wherein the chalcogen precursor is sulfur, selenium or tellurium.

33. The method of claim 1, wherein the chalcogen precursor is a chalcogen solution having chalcogen powder dissolved in an alkyl phosphine [(R)₃P, R=butyl, octyl] or a liquid alkylamine.

34. The method of claim 1, wherein additional reactive groups of —SH, —OH, —NH₂ and/or —COOH are added to the mixture.

35. The method of claim 1, wherein the produced metal chalcogenide nanomaterial is separated by centrifugation or solvent precipitation.

36. The method of claim 1, wherein the steps are performed in order of:
mixing the metal precursor and the chalcogen-based ligand;
adding the solvent;
adding the chalcogen precursor;
mixing and heating the mixture at the reaction temperature for the duration of reaction time.

37. A metal chalcogenide nanomaterial, produced according to the method of claim 1.
